(19) United States
(12) Patent Application Publication
(10) Pub. No.: US 2025/0126812 A1
(43) Pub. Date: Apr. 17, 2025

(54) INTEGRATED CIRCUIT FABRICATION EMPLOYING SELF-ALIGNED MASK

(71) Applicant: Taiwan Semiconductor Manufacturing Company, Ltd., Hsinchu (TW)

(72) Inventors: Meng-Hsien Lin, Tainan City (TW); Jaio-Wei Wang, Kaohsiung City (TW); Ko Chun Liu, Toufen Township (TW); Hsing-Chih Lin, Tainan City (TW); Jen-Cheng Liu, Hsin-Chu City (TW); Dun-Nian Yaung, Taipei City (TW)

(21) Appl. No.: 18/488,071

(22) Filed: Oct. 17, 2023

(51) Int. Cl. H01L 27/06

(52) U.S. Cl. CPC H10D 1/042; H10D 1/043; H10D 1/716; H10D 84/204

(57) ABSTRACT

Some embodiments relate to a method that includes depositing a first layer of hard mask material over a layer of dielectric material; etching the first layer of the hard mask material, the etched first layer of hard mask material including an etched portion having a first lateral dimension; depositing a second layer of the hard mask material over the first layer of the hard mask material; etching at least a portion of the second layer of the hard mask material, while allowing a remaining portion of the hard mask material, to expose a portion of the layer of the dielectric material that has a second lateral dimension less than the first lateral dimension; and etching a trench into the layer of the dielectric material at the exposed portion of the layer of the dielectric material.

### BACKGROUND

Each successive generation of integrated circuit (IC) technology is associated with one or more increasing metrics (e.g., the number of logic gates, transistors, and the like per IC device). Accordingly, such metrics are linked to a corresponding decrease in the smallest “critical dimension,” or feature width attainable with a particular IC process technology, or “node”. The minimum critical dimension, in turn, is based on the accuracy and precision of the photolithographic masks and other materials employed in the associated node.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a schematic side view of some embodiments of a metal-insulator-metal (MIM) capacitor structure having a reduced critical dimension obtained using a self-aligned mask, according to the present disclosure.

FIG. 1B illustrates a schematic plan view of some embodiments of a three-dimensional (3D) MIM capacitor structure having a reduced critical dimension obtained using a self-aligned mask, according to the present disclosure.

FIG. 1C illustrates a schematic plan view of some embodiments of a two-dimensional (2D) MIM capacitor structure having a reduced critical dimension obtained using a self-aligned mask, according to the present disclosure.

FIG. 2 illustrates a structural side view of some embodiments of an IC device including a MIM capacitor structure having a reduced critical dimension obtained using a self-aligned mask, according to the present disclosure.

FIGS. 3A through 3N illustrate side views of some embodiments of an IC device including a MIM capacitor structure having a reduced critical dimension obtained using a self-aligned mask at various stages of manufacture, according to the present disclosure.

FIG. 4 illustrates a methodology of forming an IC device including a MIM capacitor structure having a reduced critical dimension obtained using a self-aligned mask, in accordance with some embodiments.

FIG. 5 illustrates a structural side view of some embodiments of an IC device having a logic section and a capacitor section including a MIM capacitor structure having a reduced critical dimension obtained using a self-aligned mask, according to the present disclosure.

FIG. 6 illustrates a methodology of forming an IC device including a feature having a reduced critical dimension obtained using a self-aligned mask, in accordance with some embodiments.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

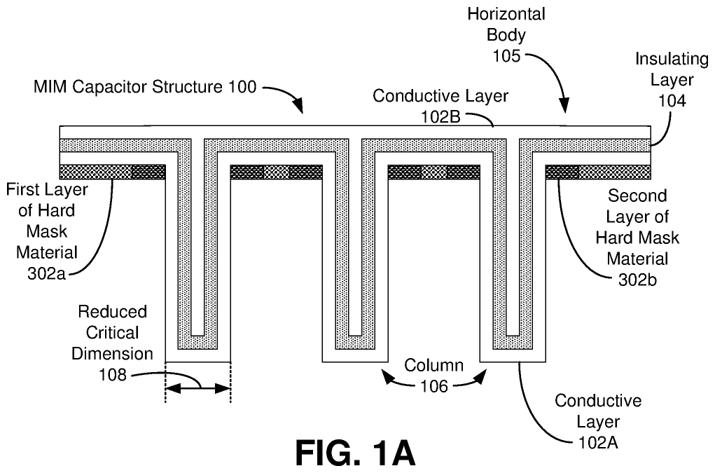

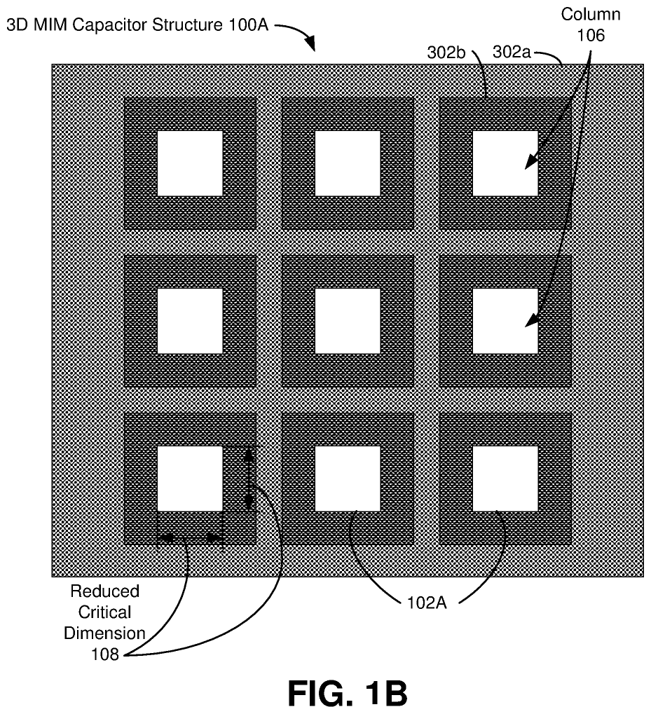

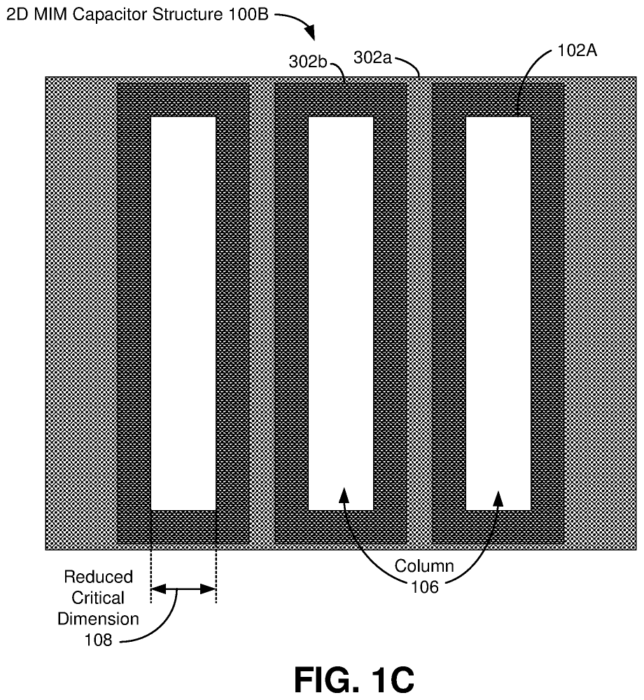

A lower bound of a critical dimension attainable in an IC device is generally limited by the particular IC node being employed to fabricate the device. This lower bound, in turn, may affect various properties of the electrical or electronic components created in the device. For example, as described below in conjunction with FIGS. 1A-1C, in the case of a two-dimensional (2D) or three-dimensional (3D) metal-insulator-metal (MIM) capacitor, the critical dimension determines the width of each “column” or extension of the capacitor. Accordingly, a higher critical dimension reduces the number of columns that may be implemented in a capacitor within a particular footprint, and hence lowers the maximum amount of capacitance that may be realized.

To address these issues, the present disclosure provides some embodiments of a method of fabricating an IC device with one or more features having a reduced critical dimension obtained using a self-aligned mask. In some embodiments, a first layer of hard mask material may be deposited over a layer of dielectric material. The first layer of hard mask material may then be etched, and the etched portion may have a first lateral dimension. A second layer of the hard mask material may be deposited over the first layer. At least a portion of the second layer of the hard mask material may then be etched to expose a portion of the layer of dielectric material that has a second lateral dimension less than the first lateral dimension. A trench may then be etched into the layer of dielectric material at the exposed portion of the dielectric material.

Accordingly, use of some embodiments of the method may provide a feature, such as the resulting trench described above, that may have the second lateral dimension, which represents a smaller critical dimension than the first lateral dimension of the etched portion of the layer of hard mask material. In some embodiments, the reduced critical dimension may improve or augment some characteristic of a component (e.g., a 3D MIM capacitor) of the IC device.

FIG. 1A illustrates a schematic side view of some embodiments of a MIM capacitor structure 100 having a reduced critical dimension 108 obtained using a self-aligned mask, according to the present disclosure. MIM capacitor structure 100 includes a first conductive layer 102A, an insulating layer 104, and a second conductive layer 102B that serve as the metal, insulator, and metal layers, respectively, of MIM capacitor structure 100. Further, MIM capacitor structure 100, using the layers 102A, 104, and 102B, includes a horizontal body 105 and a plurality of columns 106 extending downward from horizontal body 105. In addition, a first layer 302a and a second layer 302b of a hard mask material may underlie horizontal body 105 and may be employed to create reduced critical dimension 108, as described in greater detail below.

In some embodiments, reduced critical dimension 108 results in narrower columns 106 that, in turn, would allow the use of a greater number of columns 106 within a particular footprint of MIM capacitor structure 100 (e.g., as defined by a length of horizontal body 105). For example, where three columns 106 are depicted in FIG. 1A, a critical dimension that is larger than reduced critical dimension 108 may allow for two columns 106 in MIM capacitor structure 100.

FIG. 1B illustrates a schematic plan view of some embodiments of a 3D MIM capacitor structure 100A having a reduced critical dimension 108 obtained using a self-aligned mask, according to the present disclosure. Viewed from below 3D MIM capacitor structure 100A, 3D MIM capacitor structure 100A includes nine columns 106, as formed on a surface of first conductive layer 102A extending through first layer 302a and second layer 302b of hard mask material, in a 2D (3-by-3) array. Within the array, each column 106 may exhibit reduced critical dimension 108 in two dimensions, as depicted in FIG. 1B. Consequently, a larger array (e.g., a 3-by-3 array) of columns 106 may be implemented compared to a smaller array (e.g., a 2-by-2 array) of columns 106 to which a device with a larger critical dimension may be restricted.

FIG. 1C illustrates a schematic plan view of some embodiments of a 2D MIM capacitor structure 100B having a reduced critical dimension 108 obtained using a self-aligned mask, according to the present disclosure. Viewing from below 2D MIM capacitor structure 100B, 2D MIM capacitor structure 100B includes three elongated columns 106, as formed on a surface of first conductive layer 102A extending through first layer 302a and second layer 302b of hard mask material, in a single row. Within the row, each column 106 may exhibit reduced critical dimension 108 in one dimension, as depicted in FIG. 1C. Consequently, a larger number (e.g., three) of columns 106 may be used compared to a smaller number (e.g., two) of columns 106 to which a device with a larger critical dimension may be limited.

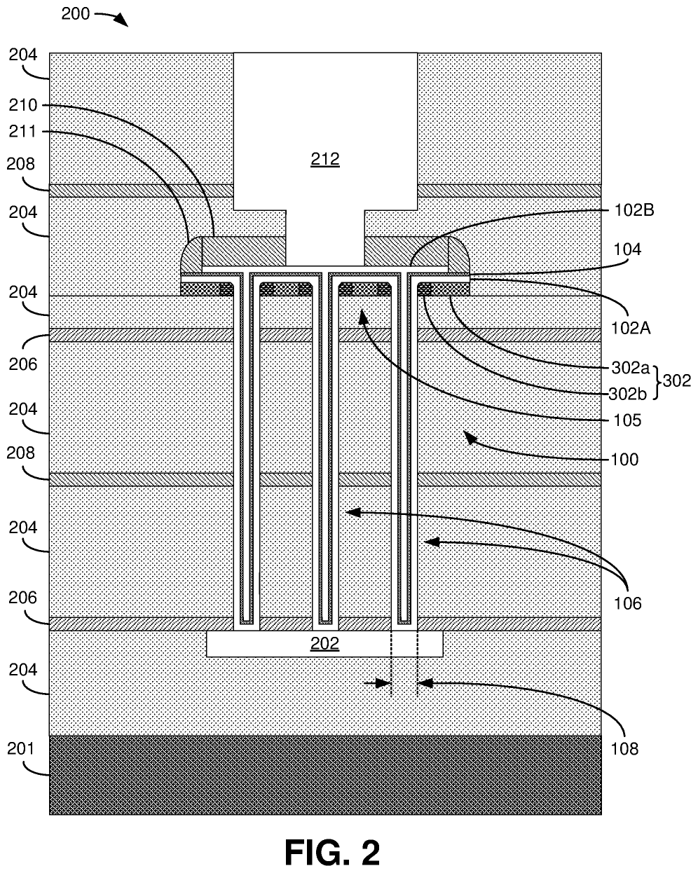

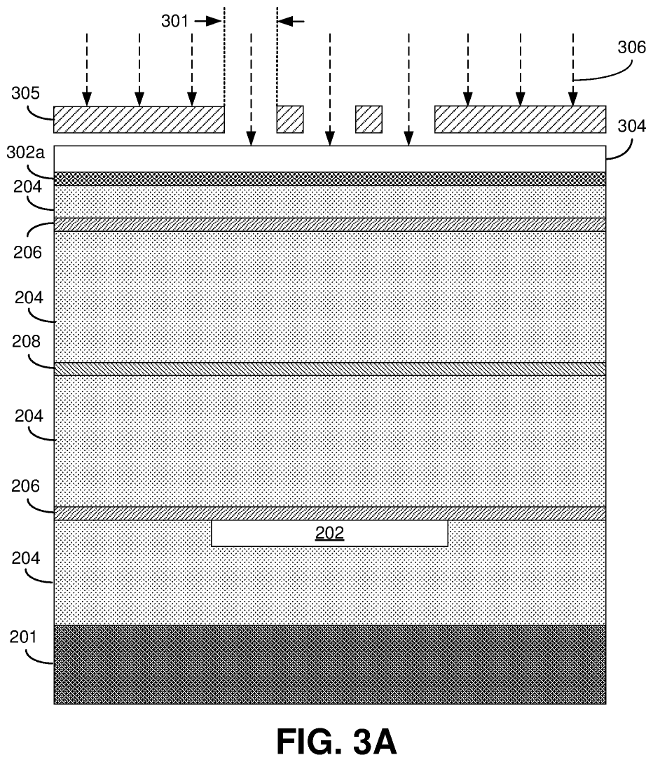

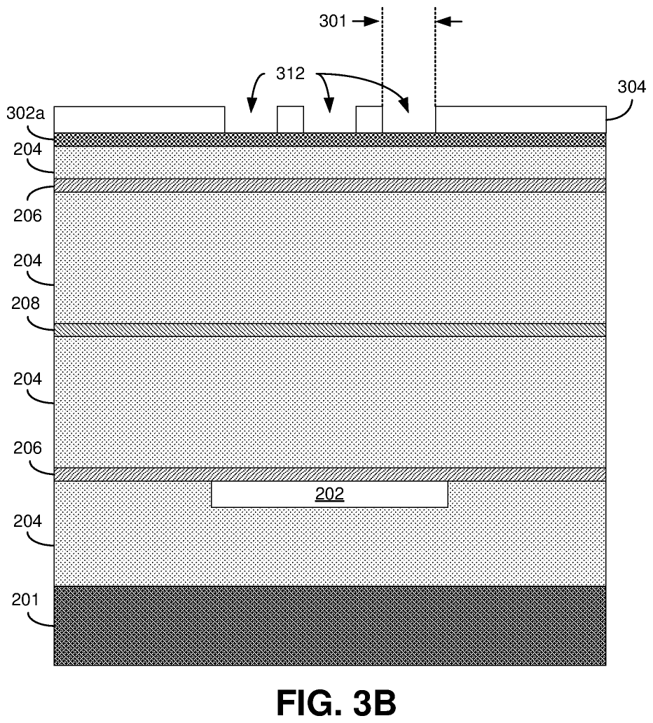

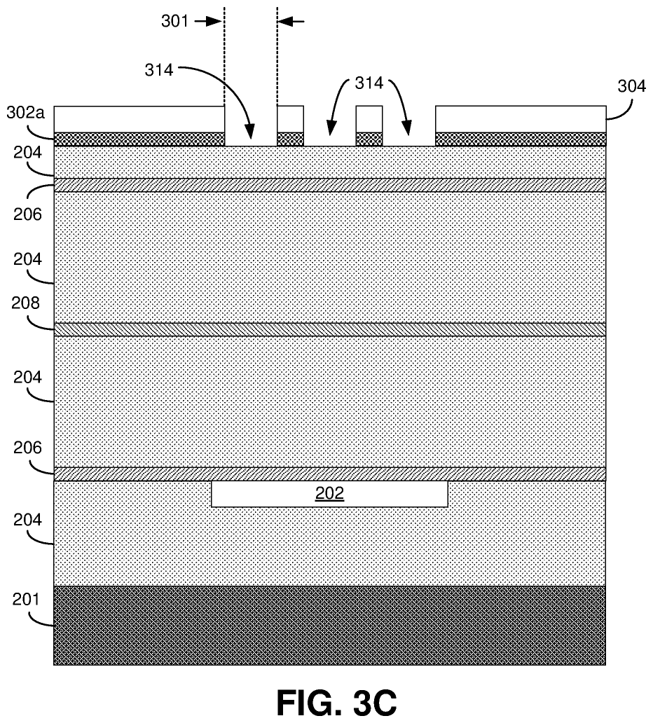

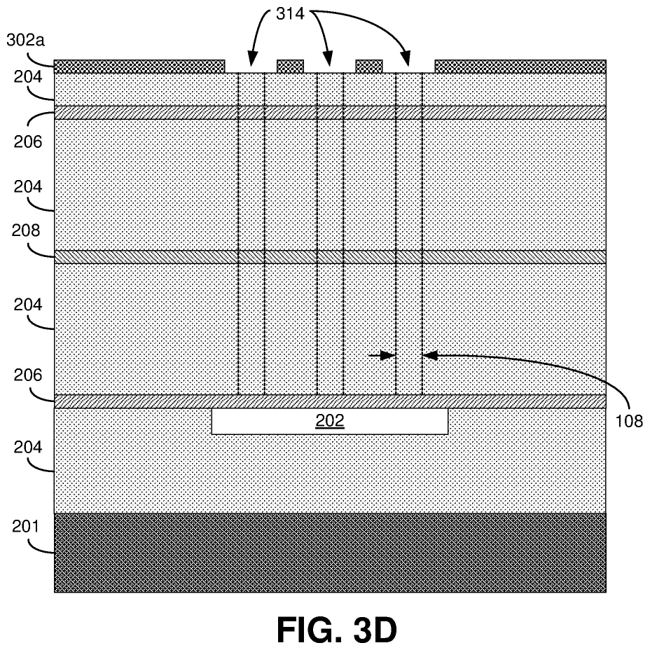

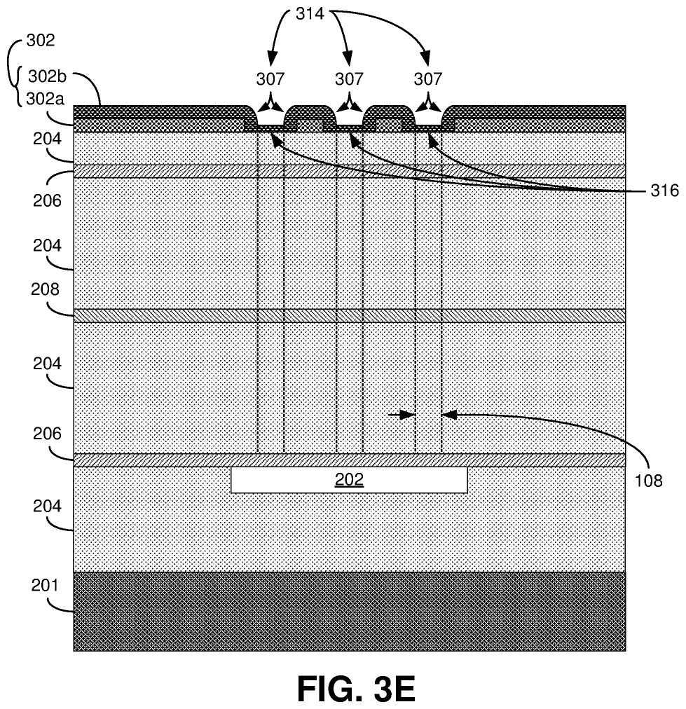

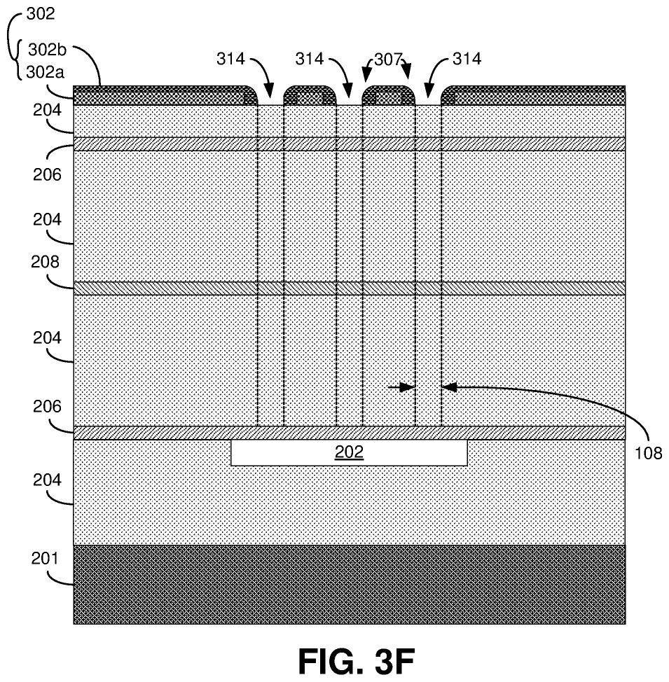

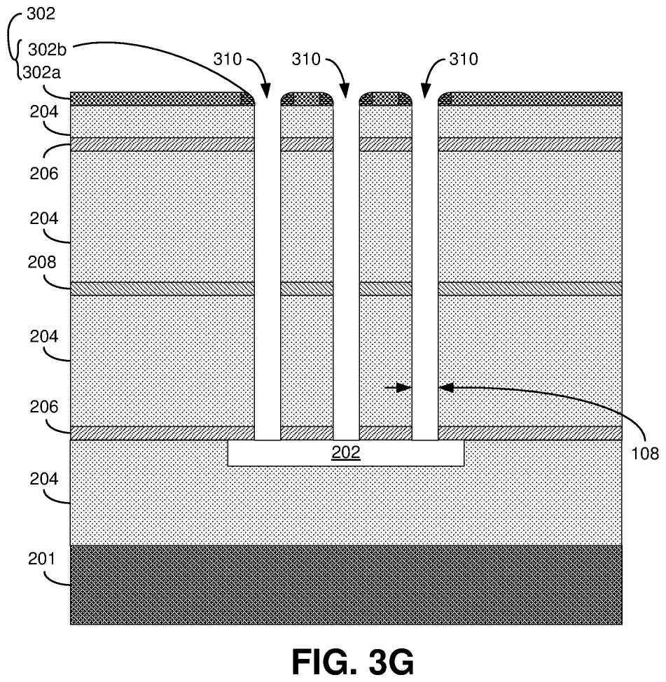

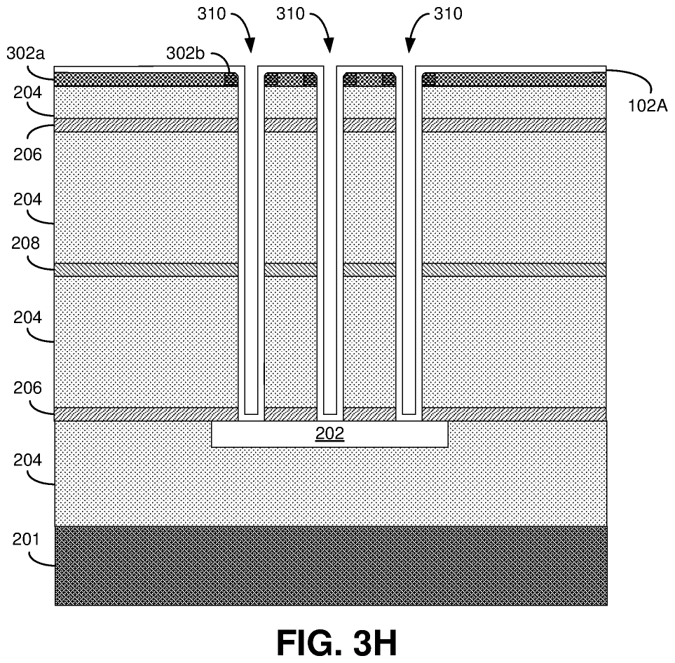

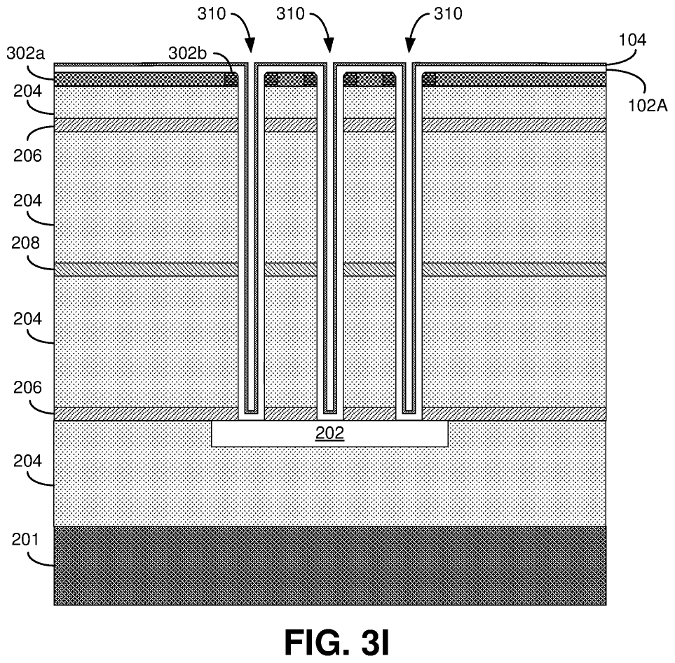

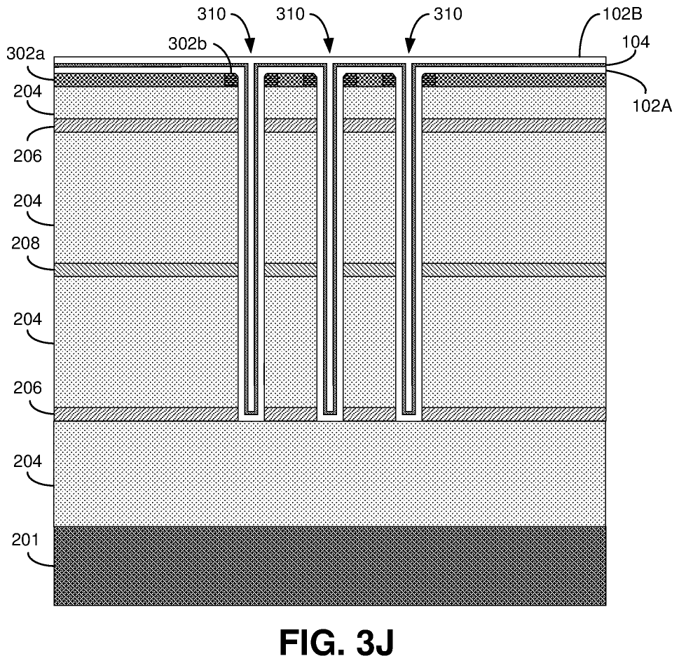

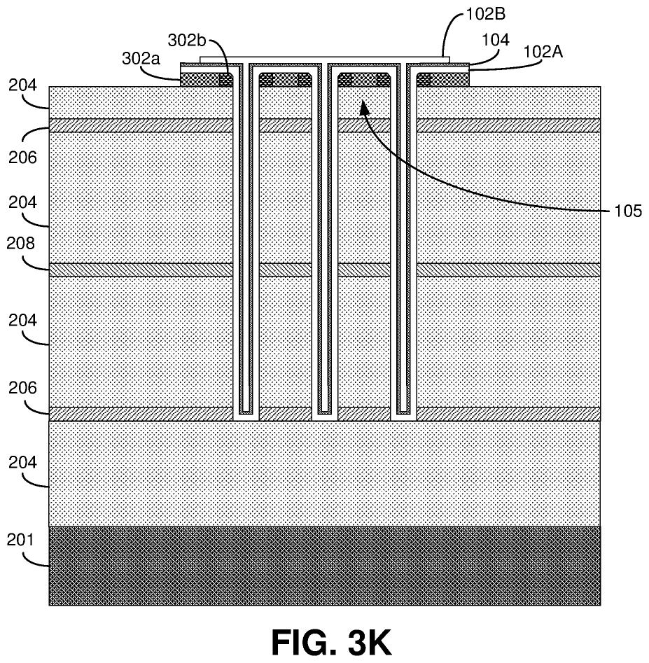

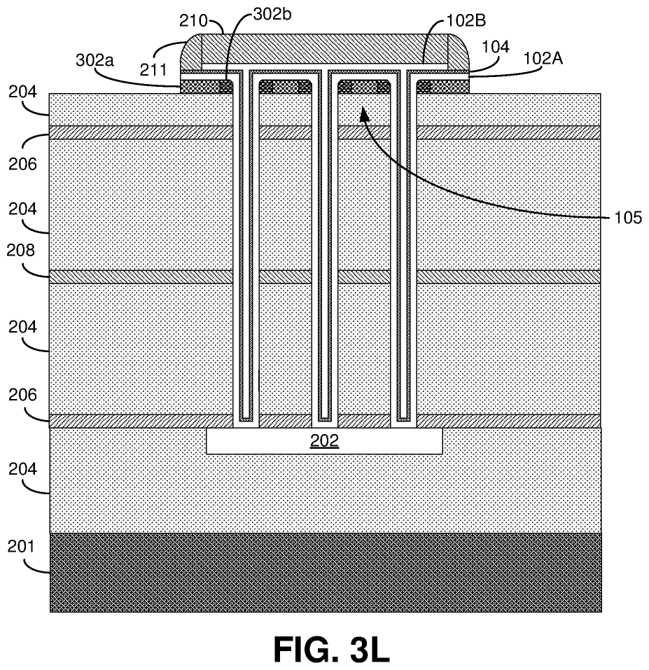

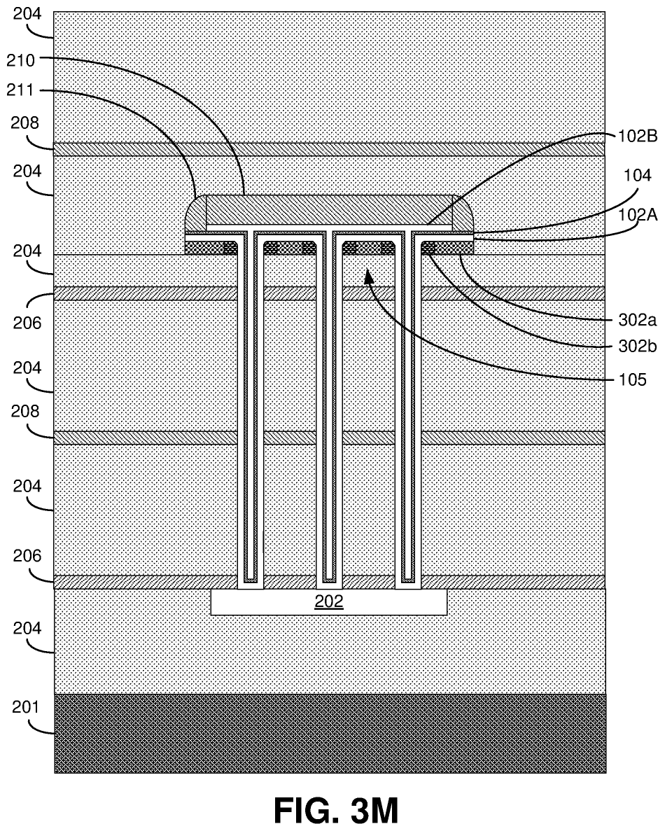

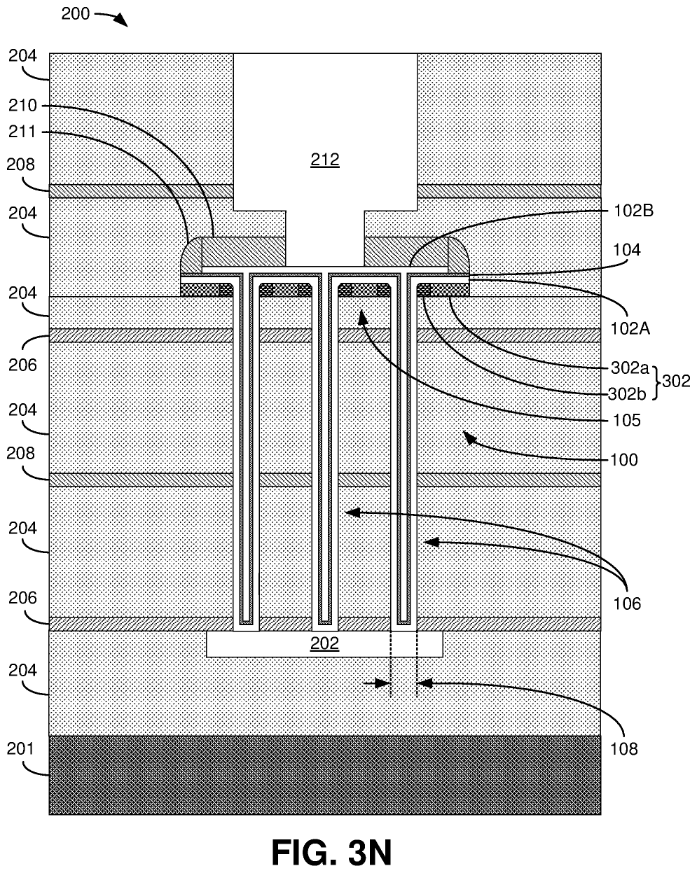

FIG. 2 illustrates a structural side view of some embodiments of an IC device 200 including a MIM capacitor structure 100 having a reduced critical dimension 108 obtained using a self-aligned mask, according to the present disclosure. While the discussion regarding FIG. 2 and FIGS. 3A-3N are directed to MIM capacitor structure 100 that possesses reduced critical dimension 108, other IC structures (e.g., any other capacitor or non-capacitor structure) may benefit from a reduced critical dimension in other embodiments.

IC device 200 may include a substrate 201 (e.g., a silicon substrate) over which a plurality of dielectric layers 204, 206, and 208 may be disposed. As illustrated in FIG. 2, a first dielectric layer 204 is disposed over substrate 201, and first dielectric layer 204 may have disposed therein a first electrode 202, over which others of the plurality of dielectric layers 204, 206, and 208 may be disposed. In some embodiments, each of dielectric layers 204, 206, and 208 may include one or more dielectric materials, including, but not limited to, silicon oxide (SiOₓ) (e.g., silicon oxide (SiO₂)), silicon nitride (SiN), silicon carbide (SiC), carbon doped silicon dioxide, silicon oxynitride, borosilicate glass (BSG), phosphorus silicate glass (PSG), borophosphosilicate (BPSG), fluorosilicate glass (FSG), undoped silicate glass (USG), a porous dielectric material, or the like. For example, dielectric layers 204 may include silicon oxide, dielectric layers 206 may include silicon carbide, and dielectric layers 208 may include silicon nitride. Also, while a particular arrangement and thickness of dielectric layers 204, 206, and 208 is depicted in FIG. 2, other arrangements and thicknesses are possible in other embodiments.

Disposed within dielectric layers 204, 206, and 208 is a MIM capacitor structure 100 having a horizontal body 105 and columns 106 extending therefrom. While three columns 106 are shown in FIG. 2, two or more such columns 106 may be employed in other embodiments. Additionally, an end of each of columns 106 may contact first electrode 202 such that first electrode 202 may serve as an electrical connection for MIM capacitor structure 100.

In some embodiments, underlying horizontal body 105 among columns 106 is a layer of hard mask material 302 that includes a first layer 302a and a second layer 302b used to trench dielectric layers 204, 206, and 208 to form columns 106. Also, in some embodiments, as described in greater detail below, hard mask material 302 is self-aligned in response to a broad, or “blanket,” etching operation.

As discussed above in connection with FIG. 1A, horizontal body 105 and columns 106 each include three layers forming the MIM structure: first conductive layer 102A, insulating layer 104, and second conductive layer 102B. Collectively, horizontal body 105 and columns 106 maintain the layered structure of first conductive layer 102A, insulating layer 104, and second conductive layer 102B such that the length of each column 106 contributes significantly to the overall capacitance value of MIM capacitor structure 100. Consequently, the width of each column 106, as determined by reduced critical dimension 108, influences the number of columns 106 employable within the footprint of horizontal body 105, and thus impacts the capacitance value of MIM capacitor structure 100.

As also shown in FIG. 2, a dielectric cover layer 210 is disposed over second conductive layer 102B of horizontal body 105. In addition, a dielectric spacer 211 may be disposed over insulating layer 104 and surround dielectric cover layer 210 and second conductive layer 102B. In some embodiments, dielectric cover layer 210 and dielectric spacer 211 may be made of the same dielectric material, such as silicon nitride, although other dielectric materials may be used in other embodiments.

In some embodiments, a second electrode 212 may contact second conductive layer 102B. Second electrode 212 may include a conductive material, such as copper, a copper alloy, another metal, or another conductive material. Also, in some embodiments, second electrode 212 may have a wider upper portion and a narrower lower portion. The narrower lower portion may extend through dielectric cover layer 210 to make contact with second conductive layer 102B.

First electrode 202 and second electrode 212 may serve as the two electrical connections for MIM capacitor structure 100 of IC device 200. In some embodiments, MIM capacitor structure 100 may serve as a component in a digital or analog circuit, such as a bypass or decoupling capacitor (e.g., for direct current (DC) voltages, such as power supply voltages). Further, due to reduced critical dimension 108 corresponding to the width of columns 106, a greater number of columns 106 (e.g., three instead of two) may be employed, thus increasing the capacitance value without increasing the footprint (e.g., as indicated by the length and width of horizontal body 105) of MIM capacitor structure 100.

FIGS. 3A-3N illustrate cross-sectional views of some embodiments of an IC device (e.g., IC device 200 of FIG. 2) at various stages of manufacture, where the IC device possesses a reduced critical dimension obtained using a self-aligned mask. Although FIGS. 3A-3N are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

FIG. 3A illustrates a first electrode 202 over which a plurality of dielectric layers 204, 206, and 208 are disposed. In some embodiments, a substrate 201 (e.g., a silicon substrate) may support a first dielectric layer 204, within which first electrode 202 may be formed, followed by the forming of successive additional dielectric layers 204, 206, and 208. As illustrated in FIG. 3A, relatively thin structures of dielectric layers 206 and 208 may be formed in an alternating manner between thicker structures of dielectric layer 204, although many other structures and orders of formation may be employed using dielectric layers 204, 206, and/or 208. As indicated above, in some embodiments, each of dielectric layers 204, 206, and 208 may include one or more dielectric materials, including, but not limited to, silicon oxide, silicon nitride, and silicon carbide. For example, dielectric layers 204 may include silicon oxide, dielectric layers 206 may include silicon carbide, and dielectric layers 208 may include silicon nitride, although other materials and combinations are also possible.

Over dielectric layers 204, 206, and 208, a first layer of hard mask material 302 may be formed (e.g., deposited). In some embodiments, the first layer of hard mask material 302 may include, but is not limited, a metal (e.g., aluminum (Al), titanium nitride (TiN), or another metal or metal alloy) or a dielectric material (e.g., silicon nitride (SiN), silicon carbide (SiC), or another dielectric material).

A photoresist material layer 304 may then be formed (e.g., deposited) over the first layer of hard mask material 302. As used in FIG. 3A, photoresist material layer 304 may include a positive photoresist material. However, a negative photoresist material may be employed for photoresist material layer 304 in other embodiments.

A photomask 305 may be positioned over photoresist material layer 304 and may include open features having a first lateral dimension 301. In some embodiments, first lateral dimension 301 may be a smallest critical dimension directly obtainable by way of photomask 305. Thereafter, light 306 (e.g., ultraviolet (UV) light) may be directed onto photomask 305, which may allow some portion of light 306 to impact portions of photoresist material layer 304 corresponding with the open features of photomask 305. Thereafter, a developer may be used to remove the portions of the photoresist material layer 304 that were exposed to light 306, resulting in a first plurality of voids 312, each having first lateral dimension 301, as depicted in FIG. 3B.

FIG. 3C illustrates the removal (e.g., etching) of a second plurality of voids 314 of the first layer 302a of hard mask material 302 associated with the first plurality of voids 312 of photoresist material layer 304. Each of the second plurality of voids 314 has first lateral dimension 301 associated with photoresist material layer 304.

FIG. 3D illustrates the removal of photoresist material layer 304 after the creation of the second plurality of voids 314. Also depicted is a desired second lateral dimension 108 to be created in association with each of the second plurality of voids 314.

FIG. 3E illustrates the forming (e.g., deposition) of a second layer 302b of hard mask material 302 over the first layer 302a of hard mask material 302. In some embodiments, the second layer 302b of hard mask material 302 is formed on upper surfaces and sidewalls of the first layer 302a of hard mask material 302. In some embodiments, the forming of the second layer 302b results in the formation of a barrier 307 over the underlying dielectric layer (e.g., uppermost dielectric layer 204) for each of the second plurality of voids 314. Barrier 307 also lies within an interior wall of its associated void. Also resulting from the forming of the second layer 302b of hard mask material 302 is a fill layer 316 over the underlying dielectric layer within barrier 307 of each of the second plurality of voids 314. In some embodiments, the width of the fill layer 316 within barrier 307 is associated with second lateral dimension 108. In some embodiments, barrier 307 and fill layer 316 of each of the second plurality of voids 314 is formed as a result of a reduced level of conformity to the first layer 302a of hard mask material 302. In some embodiments, the second layer 302b of hard mask material 302 may be a same material as the hard mask material of the first layer 302a. In other embodiments, the second layer 302b of hard mask material 302 may be a different material than the first layer 302a of the hard mask material 302.

FIG. 3F illustrates the removal (e.g., etching) of at least a portion of hard mask material 302 (e.g., a portion of the second layer 302b of hard mask material 302) to remove at least fill layer 316 of each of the second plurality of voids 314 to expose a portion of the underlying dielectric layer (e.g., uppermost dielectric layer 204) within barrier 307 associated with each of the second plurality of voids 314. In some embodiments, this removal may be a “blanket” etching of an entire area occupied by the second layer 302b of hard mask material 302. In some embodiments, such etching results in exposed areas of the underlying dielectric layer that have a width of a second lateral dimension 108, which also may be referred to as reduced critical dimension 108 relative to first lateral dimension 301 of FIG. 3C. In some embodiments, second lateral dimension 108 may be 35% to 65% less than first lateral dimension 301, 50% less than first lateral dimension 301, or other similar values.

FIG. 3G illustrates a removal (e.g., etching) of a plurality of trenches 310 through one or more of the plurality of dielectric layers 204, 206, and 208 at the exposed portions of the uppermost dielectric layer. In some embodiments, the plurality of trenches 310 define where columns 106 of MIM capacitor structure 100 will be subsequently formed. Also, in some embodiments, the etching of the plurality of trenches 310 is terminated at first electrode 202. In some embodiments, this etching may also remove an additional portion of the first layer 302a of the hard mask material 302, thus reducing a thickness of the remaining hard mask material 302.

FIG. 3H illustrates the forming (e.g., deposition) of a first conductive layer 102A over the remaining hard mask material 302 and extending into the plurality of trenches 310. In some embodiments, the forming of first conductive layer 102A is performed with significant conformity such that first conductive layer 102A lines the plurality of trenches 310 and extends to first electrode 202. In other embodiments, the remaining hard mask material 302 may be removed prior to the forming of first conductive layer 102A over uppermost dielectric layer 204 and the plurality of trenches 310.

FIG. 3I illustrates the forming (e.g., deposition) of an insulating layer 104 over first conductive layer 102A. In some embodiments, insulating layer 104 may extend into the plurality of trenches 310. In some embodiments, the forming of insulating layer 104 is performed with significant conformity such that insulating layer 104 covers first conductive layer 102A throughout the plurality of trenches 310.

FIG. 3J illustrates the forming (e.g., deposition) of a second conductive layer 102B over insulating layer 104, including extending into and filling the plurality of trenches 310. In some embodiments, the forming of second conductive layer 102B may be performed with significant conformity to facilitate the filling of the plurality of trenches 310. Further, in some embodiments, the forming of second conductive layer 102B may result in a substantially planar surface provided by second conductive layer 102B.

FIG. 3K illustrates the removal (e.g., etching) of portions of second conductive layer 102B, insulating layer 104, first conductive layer 102A, and hard mask material 302 to form a horizontal body (e.g., horizontal body 105 of FIG. 2) for MIM capacitor structure 100. In some embodiments, second conductive layer 102B is etched to expose an outer perimeter portion of insulating layer 104.

FIG. 3L illustrates the forming (e.g. deposition) of a dielectric cover layer 210 over second conductive layer 102B and the forming of a dielectric spacer 211 over insulating layer 104 and surrounding dielectric spacer 211. In some embodiments, dielectric cover layer 210 and dielectric spacer 211 are formed simultaneously. Also, in some embodiments, dielectric cover layer 210 and dielectric spacer 211 may include the same dielectric material (e.g., silicon nitride). In some embodiments, the forming of dielectric cover layer 210 and dielectric spacer 211 are performed conformally with respect to second conductive layer 102B and insulating layer 104 to cover the corresponding materials.

FIG. 3M illustrates the forming (e.g., deposition) of at least one additional dielectric layer (e.g., one or more dielectric layers 204, 206, and/or 208) over previously uppermost dielectric layer 204, dielectric cover layer 210, and dielectric spacer 211. In some embodiments, the additional dielectric layers include two dielectric layers 204 with an intervening dielectric layer 208. However, other numbers and combinations of dielectric layers 204, 206, and/or 208 may be employed in other embodiments.

FIG. 3N illustrates the forming (e.g., etching and deposition) of a second electrode 212 through the at least one additional dielectric layer and dielectric cover layer 210 to contact second conductive layer 102B. In some embodiments, a wide upper region is etched, and a narrower lower region is etched that extends through dielectric cover layer 210 to second conductive layer 102B. A conductive material, such as a metal (e.g., copper), a metal alloy, or another conductive material, may then be deposited in the etched regions to form second electrode 212. First electrode 202 and second electrode 212 thus may serve as contact points for other circuitry within IC device 200 to access MIM capacitor structure 100. As indicated above, the capacitance may be enhanced due to the self-aligned hard mask material 302 facilitating a reduced critical dimension 108 that results in the ability to employ more columns 106 for MIM capacitor structure 100.

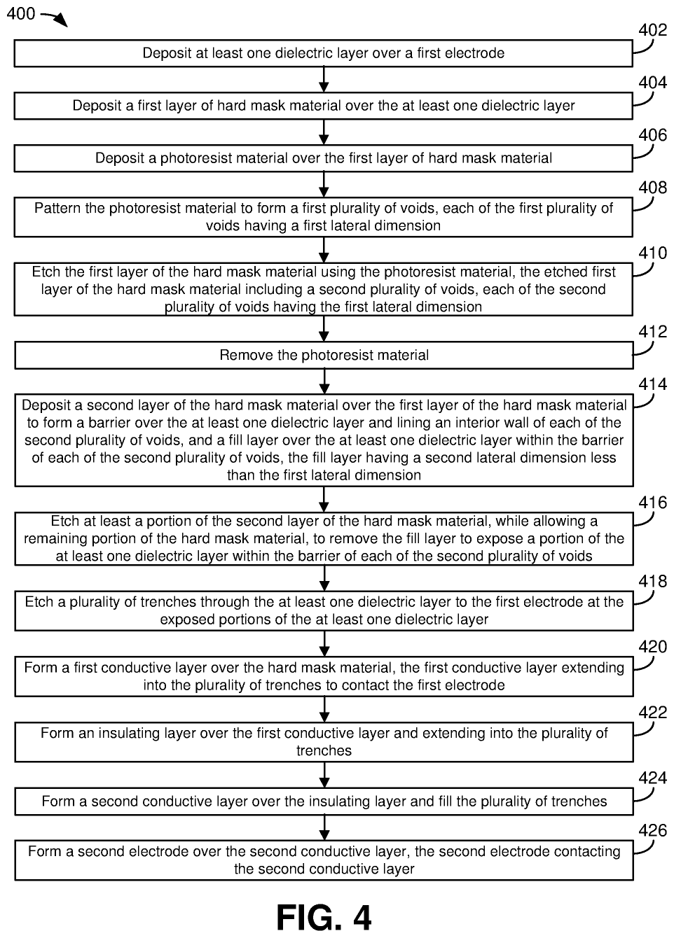

FIG. 4 illustrates a methodology 400 of forming an IC device (e.g., IC device 200 of FIG. 2) including a MIM capacitor structure (e.g., MIM capacitor structure 100 of FIG. 2) having a reduced critical dimension 108 obtained using a self-aligned mask, in accordance with some embodiments. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

Acts 402 through 426 may correspond, for example, to the structure previously illustrated in FIGS. 3A through 3N in some embodiments. At Act 402, for example, at least one dielectric layer (e.g., one or more dielectric layers 204, 206, and 208) may be deposited over a first electrode (e.g., first electrode 202). Further, in some embodiments, as illustrated in FIG. 3A, the first electrode may be formed over a substrate (e.g., substrate 201) and a lowermost dielectric layer (e.g., lowermost dielectric layer 204 of FIG. 3A). At Act 404, a first layer of hard mask material (e.g., first layer 302a of hard mask material 302 of FIG. 3A) is deposited over the at least one dielectric layer. At Act 406, a photoresist material (e.g., photoresist material layer 304) is deposited over the first layer of the hard mask material. At Act 408, the photoresist material is patterned (e.g., using photomask 305 of FIG. 3A) to form a first plurality of voids (e.g., first plurality of voids 312 of FIG. 3B). FIGS. 3A and 3B illustrate cross-sectional views of some embodiments corresponding to Acts 402 through 408.

At Act 410, the first layer of the hard mask material is etched using the photoresist material, where the etched first layer of the hard mask material includes a second plurality of voids (e.g., second plurality of voids 314 of FIG. 3C). In some embodiments, each of the second plurality of voids has a first lateral dimension (e.g., first lateral dimension 301). FIG. 3C illustrates a cross-sectional view of some embodiments corresponding to Act 410.

At Act 412, the photoresist material may be removed. FIG. 3D illustrates a cross-sectional view of some embodiments corresponding to Act 412.

At Act 414, a second layer of the hard mask material (e.g., second layer 302b of hard mask material 302 of FIG. 3E) is formed over the first layer of the hard mask material. In some embodiments, the second layer of the hard mask material forms a barrier (e.g., barrier 307 of FIG. 3E) over the at least one dielectric layer and lining an interior wall of each of the second plurality of voids, as well as a fill layer (e.g., fill layer 316 of FIG. 3E) over the at least one dielectric layer within the barrier of each of the second plurality of voids. In some embodiments, the fill layer has a second lateral dimension (e.g., second lateral dimension 108 of FIG. 3E) that is less than the first lateral dimension. FIG. 3E illustrates a cross-sectional view of some embodiments corresponding to Act 414.

At Act 416, at least a portion of the second layer of the hard mask material is etched while allowing a portion of the hard mask material to remain. In some embodiments, this etching removes the fill layer to expose a portion of the at least one dielectric layer within the barrier of each of the second plurality of voids. Also, in some embodiments, the exposed portion of the at least one dielectric layer has the second lateral dimension. In some embodiments, this etching may be characterized as an overall or “blanket” etching of the hard mask material. FIG. 3F illustrates a cross-sectional view of some embodiments corresponding to Act 416.

At Act 418, a plurality of trenches (e.g., plurality of trenches 310 of FIG. 3G) is etched through the at least one dielectric layer to the first electrode at the exposed portions of the at least one dielectric layer. FIG. 3G illustrates a cross-sectional view of some embodiments corresponding to Act 418.

At Act 420, a first conductive layer (e.g., first conductive layer 102A of FIG. 3H) is formed over the hard mask material. In some embodiments, the first conductive layer extends into the plurality of trenches to contact the first electrode. Further, in some embodiments, the first conductive layer may line the plurality of trenches and extend to the first electrode due to the forming of the first conductor being performed with significant conformity with the hard mask material and the plurality of dielectric layers. FIG. 3H illustrates a cross-sectional view of some embodiments corresponding to Act 420.

At Act 422, an insulating layer (e.g., insulating layer 104 of FIG. 3I) is formed over the first conductive layer and extends into the plurality of trenches. In some embodiments, the insulating layer is formed with significant conformity with the first conductive layer. FIG. 3I illustrates a cross-sectional view of some embodiments corresponding to Act 422.

At Act 424, a second conductive layer (e.g., second conductive layer 102B of FIG. 3J) is formed over the insulating layer and fills the plurality of trenches. In some embodiments, the second conductive layer 102B may be formed with significant conformity with the insulating layer to facilitate the filling of the plurality of trenches 310. Also, in some embodiments, the second conductive layer may present a substantially planar upper surface. FIG. 3J illustrates a cross-sectional view of some embodiments corresponding to Act 424.

At Act 426, a second electrode (e.g., second electrode 212 of FIG. 3N) is formed over the second conductive layer to contact the second conductive layer. Consequently, in some embodiments, the first and second electrodes may serve as contact points to access the MIM capacitor structure. Moreover, the resulting capacitance may be enhanced due to the self-aligned hard mask material described above facilitating the reduced critical dimension 108 to enable the use of more columns for the MIM capacitor structure.

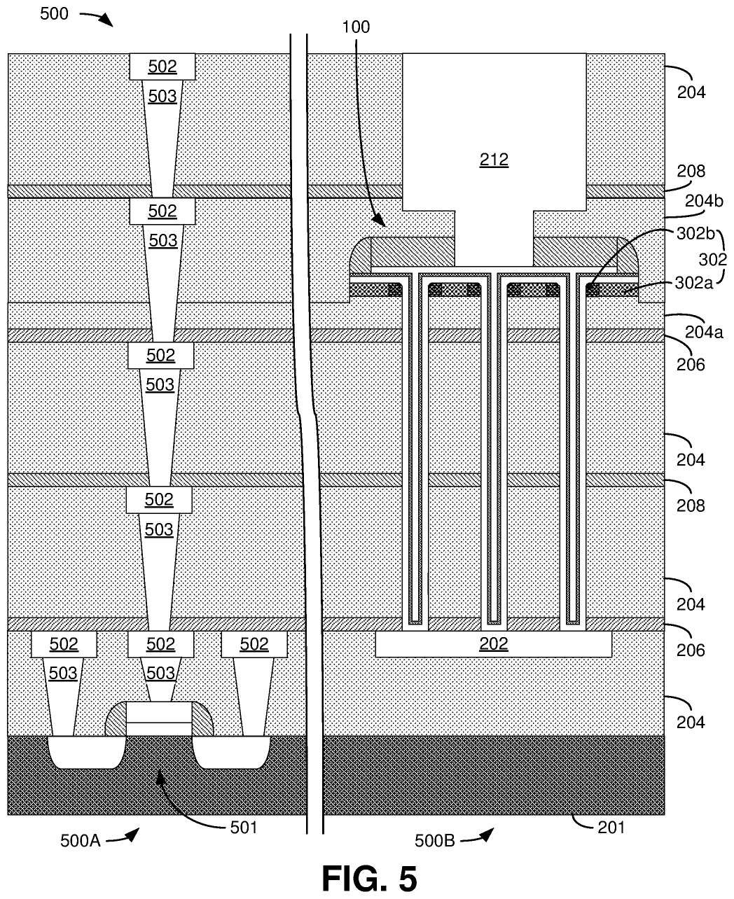

FIG. 5 illustrates a structural side view of some embodiments of an IC device 500 having a logic section 500A and a capacitor section 500B including a MIM capacitor structure 100 having a reduced critical dimension 108 obtained using a self-aligned mask, according to the present disclosure. In some embodiments, MIM capacitor structure 100 is configured among a plurality of dielectric layers 204, 206, and 208, as illustrated in FIG. 2. In some embodiments, a first dielectric layer 204a may surround an upper part of the plurality of columns and a second dielectric layer 204b may be disposed over the first dielectric layer 204a and around a horizontal part of MIM capacitor structure 100. In some embodiments, the first dielectric layer 204a may comprise an upper surface that is laterally outside of the hard mask material 302. In some embodiments, the first dielectric layer 204a may be recessed below a bottom of the hard mask material 302 so that the second dielectric layer 204b extends to below the bottom of the hard mask material 302.

In some embodiments, as discussed earlier, the hard mask material 302 may include a first layer 302a of the hard mask material 302 and a second layer 302b of the hard mask material 302 arranged along sidewalls of the first layer 302a. In some embodiments, the first layer 302a may include or be a same material as the second layer 302b. In other embodiments, the first layer 302a may include and/or be a different material than the second layer 302b. In some embodiments, the second layer 302b of hard mask material 302 may have a rounded outer corner facing MIM capacitor structure 100.

In some embodiments, the same plurality of dielectric layers 204, 206, and 208 may be employed in the logic section 500A, which may include one or more electronic circuits that include, for example, a transistor 501 that may be connected to other components in either or both of the logic section 500A and the capacitor section 500B (e.g., MIM capacitor structure 100) by way of one or more vias 503 and connected metal structures 502.

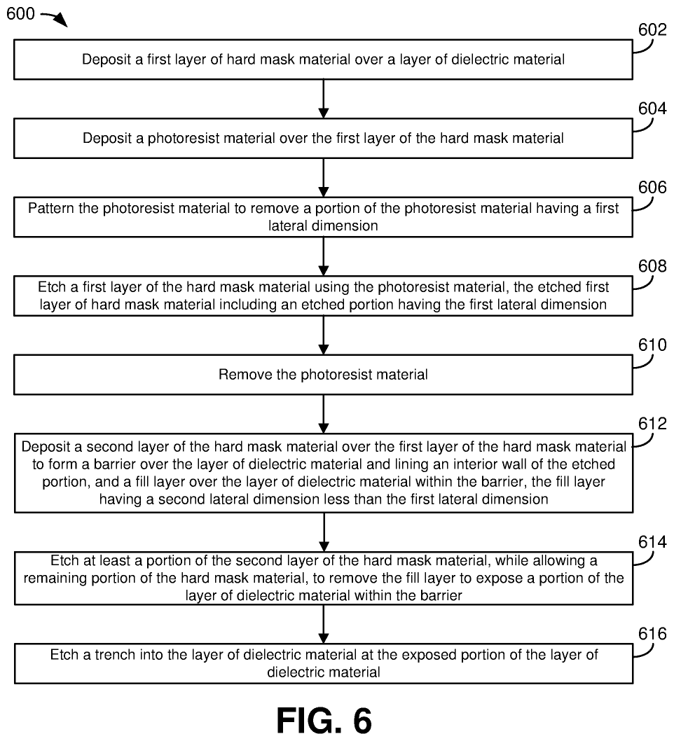

While the reduced critical dimension resulting from a self-aligned hard mask material is described in conjunction with a particular electrical component (e.g., MIM capacitor structure 100 of FIG. 2), other components or structures of an IC device may benefit from application of the same principles. To that end, FIG. 6 illustrates a methodology 600 of forming an IC device including a feature having a reduced critical dimension obtained using a self-aligned mask, in accordance with some embodiments. Such a feature may be employed in any type of structure of an IC device to improve some characteristic or aspect of that structure.

At Act 602, a first layer of hard mask material (e.g., first layer 302a of hard mask material 302 of FIG. 3A) is deposited over a layer of dielectric material (e.g., uppermost dielectric layer 204 of FIG. 3A). At Act 604, a photoresist material (e.g., photoresist material layer 304 of FIG. 3A) is deposited over the first layer of the hard mask material. At Act 606, the photoresist material is patterned (e.g., using photomask 305 of FIG. 3A) to remove a portion of the photoresist material (e.g., one of the first plurality of voids 312 of FIG. 3B) having a first lateral dimension (e.g., first lateral dimension 301 of FIG. 3B). FIGS. 3A and 3B illustrate cross-sectional views of some embodiments corresponding to Acts 602 through 606.

At Act 608, the first layer of hard mask material is etched using the photoresist material, where the etched first layer of the hard mask material includes an etched portion (e.g., one of the second plurality of voids 314) having the first lateral dimension. FIG. 3C illustrates a cross-sectional view of some embodiments corresponding to Act 608.

At Act 610, the photoresist material may be removed. FIG. 3D illustrates a cross-sectional view of some embodiments corresponding to Act 610.

At Act 612, a second layer of the hard mask material (e.g., second layer 302b of hard mask material 302 of FIG. 3E) may be formed over the first layer of hard mask material. In some embodiments, the second layer of the hard mask material forms a barrier (e.g., barrier 307 of FIG. 3E) over the at least one dielectric layer and lining an interior wall of the etched portion, and forms a fill layer (e.g., fill layer 316 of FIG. 3E) over the layer of dielectric material within the barrier. In some embodiments, the fill layer has a second lateral dimension (e.g., second lateral dimension 108 of FIG. 3E) that is less than the first lateral dimension. FIG. 3E illustrates a cross-sectional view of some embodiments corresponding to Act 612.

At Act 614, at least a portion of the second layer of the hard mask material is etched while allowing a portion of the hard mask material to remain. In some embodiments, this etching removes the fill layer to expose a portion of the at least one dielectric layer within the barrier. Also, in some embodiments, the exposed portion of the at least one dielectric layer has the second lateral dimension. In some embodiments, this etching may be characterized as blanket etching of the hard mask material. FIG. 3F illustrates a cross-sectional view of some embodiments corresponding to Act 614.

At Act 616, a trench (e.g., one of the plurality of trenches 310 of FIG. 3G) is etched through the layer of dielectric material at the exposed portion of the layer of dielectric material. In some embodiments, this trench may then be used (e.g., filled with a semiconductor, conductive, insulating, and/or dielectric material) to provide a feature having a reduced critical dimension. In some embodiments, the etching of the trench may terminated at a conductive structure (e.g., first electrode 202 of FIG. 3G). FIG. 3G illustrates a cross-sectional view of some embodiments corresponding to Act 616.

Some embodiments relate to a method. The method includes depositing a first layer of hard mask material over a layer of dielectric material; etching the first layer of the hard mask material, the etched first layer of hard mask material including an etched portion having a first lateral dimension; depositing a second layer of the hard mask material over the first layer of the hard mask material; etching at least a portion of the second layer of the hard mask material, while allowing a remaining portion of the hard mask material, to expose a portion of the layer of the dielectric material that has a second lateral dimension less than the first lateral dimension; and etching a trench into the layer of the dielectric material at the exposed portion of the layer of the dielectric material.

Some embodiments relate to another method. The method includes depositing a first layer of hard mask material over at least one dielectric layer; depositing a photoresist material over the first layer of the hard mask material; patterning the photoresist material to form a first plurality of voids, each of the first plurality of voids having a first lateral dimension; etching the first layer of the hard mask material using the photoresist material, the etched first layer of hard mask material including a second plurality of voids, each of the second plurality of voids having the first lateral dimension; removing the photoresist material; and depositing a second layer of the hard mask material over the first layer of the hard mask material. The depositing of the second layer forms a barrier over the at least one dielectric layer and lining an interior wall of each of the second plurality of voids; and a fill layer over the at least one dielectric layer within the barrier of each of the second plurality of voids, the fill layer having a second lateral dimension less than the first lateral dimension. The method further includes etching at least a portion of the second layer of the hard mask material, while allowing a remaining portion of the hard mask material, to remove the fill layer to expose a portion of the at least one dielectric layer within the barrier of each of the second plurality of voids; and etching a plurality of trenches through the at least one dielectric layer at the exposed portions of the at least one dielectric layer.

Some embodiments relate to an IC device. The IC device includes a first electrode; at least one dielectric layer disposed over the first electrode; and a capacitor structure disposed over the at least one dielectric layer and the first electrode. The capacitor structure includes a hard mask material; a horizontal structure disposed over the hard mask material and comprising a first conductive layer, an insulating layer, and a second conductive layer disposed over the at least one dielectric layer; and a plurality of columns extending from the horizontal structure through the hard mask material and the at least one dielectric layer to the first electrode, each of the plurality of columns comprising an inner region comprising the second conductive layer, an intermediate region comprising the insulating layer, and an outer region comprising the first conductive layer. The IC device further includes a second electrode disposed over and contacting the second conductive layer.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
depositing a first layer of hard mask material over a layer of dielectric material;
etching the first layer of the hard mask material, the etched first layer of the hard mask material including an etched portion having a first lateral dimension;
depositing a second layer of the hard mask material over the first layer of the hard mask material;
etching at least a portion of the second layer of the hard mask material, while allowing a remaining portion of the hard mask material, to expose a portion of the layer of the dielectric material that has a second lateral dimension less than the first lateral dimension; and
etching a trench into the layer of the dielectric material at the exposed portion of the layer of the dielectric material.

2. The method of claim 1, wherein the second lateral dimension is approximately half of the first lateral dimension.

3. The method of claim 1, wherein depositing the second layer of the hard mask material is performed with a reduced level of conformity to the first layer of the hard mask material.

4. The method of claim 1, further comprising:
continuing to etch the trench through a plurality of dielectric layers over which the layer of the dielectric material is disposed.

5. The method of claim 1, further comprising:
terminating the etching of the trench at a conductive structure over which the layer of the dielectric material is disposed.

6. The method of claim 1, further comprising:
removing the remaining portion of the hard mask material.

7. A method, comprising:
depositing a first layer of hard mask material over at least one dielectric layer;
depositing a photoresist material over the first layer of the hard mask material;
patterning the photoresist material to form a first plurality of voids, each of the first plurality of voids having a first lateral dimension;
etching the first layer of the hard mask material using the photoresist material, the etched first layer of the hard mask material including a second plurality of voids, each of the second plurality of voids having the first lateral dimension;
removing the photoresist material;
depositing a second layer of the hard mask material over the first layer of the hard mask material to form:
a barrier over the at least one dielectric layer and lining an interior wall of each of the second plurality of voids; and
a fill layer over the at least one dielectric layer within the barrier of each of the second plurality of voids, the fill layer having a second lateral dimension less than the first lateral dimension;
etching at least a portion of the second layer of the hard mask material, while allowing a remaining portion of the hard mask material, to remove the fill layer to expose portions of the at least one dielectric layer within the barrier of each of the second plurality of voids; and
etching a plurality of trenches through the at least one dielectric layer at the exposed portions of the at least one dielectric layer.

8. The method of claim 7, further comprising:
depositing the at least one dielectric layer over a first electrode before depositing the first layer of hard mask material;
forming a first conductive layer over the hard mask material, the first conductive layer extending into the plurality of trenches to contact the first electrode;
forming an insulating layer over the first conductive layer and extending into the plurality of trenches;
forming a second conductive layer over the insulating layer and filling the plurality of trenches; and
forming a second electrode over the second conductive layer, the second electrode contacting the second conductive layer.

9. The method of claim 8, further comprising:
forming a dielectric cover layer over the second conductive layer, wherein the second electrode extends through the dielectric cover layer to the second conductive layer.

10. The method of claim 9, further comprising:
forming a dielectric spacer over the insulating layer and surrounding the dielectric cover layer and the second conductive layer.

11. The method of claim 7, wherein the plurality of trenches are arranged in a plan view as a two-dimensional array.

12. The method of claim 7, wherein the plurality of trenches are arranged in a plan view as a one-dimensional array.

13. The method of claim 7, wherein each of the plurality of trenches is rectangular in a plan view.

14. The method of claim 7, wherein the second lateral dimension is approximately half of the first lateral dimension.

15. The method of claim 7, wherein depositing the second layer of the hard mask material is performed with a reduced level of conformity to the first layer of the hard mask material.

16. An IC device comprising:
a first electrode;
at least one dielectric layer disposed over the first electrode;
a capacitor structure disposed over the at least one dielectric layer and the first electrode, the capacitor structure comprising:
a hard mask material;
a horizontal structure disposed over the hard mask material and comprising a first conductive layer, an insulating layer, and a second conductive layer disposed over the at least one dielectric layer; and
a plurality of columns extending from the horizontal structure through the hard mask material and the at least one dielectric layer to the first electrode, each of the plurality of columns comprising an inner region comprising the second conductive layer, an intermediate region comprising the insulating layer, and an outer region comprising the first conductive layer; and
a second electrode disposed over and contacting the second conductive layer.

17. The IC device of claim 16, wherein the plurality of columns are arranged in a plan view as a two-dimensional array.

18. The IC device of claim 16, wherein the plurality of columns are arranged in a plan view as a one-dimensional array.

19. The IC device of claim 16, wherein each of the plurality of columns is rectangular in a plan view.

20. The IC device of claim 16, wherein each of the plurality of columns is square in a plan view.
